(19) United States
(12) Patent Application Publication
(10) Pub. No.: US 2024/0195146 A1
(43) Pub. Date: Jun. 13, 2024

(54) MONOLITHIC LASER ARRAYS WITH NON-UNIFORM LASER SPACING

(71) Applicant: II-VI Delaware, Inc., Wilmington, DE (US)

(72) Inventors: Tao Feng, Fremont, CA (US); Tsurugi Sudo, Cupertino, CA (US)

(21) Appl. No.: 18/080,319

(22) Filed: Dec. 13, 2022

(51) Int. Cl. H01S 5/024; H01S 5/026; H01S 5/40

(52) U.S. Cl. CPC H01S 5/02461; H01S 5/026; H01S 5/4025

(57) ABSTRACT

Monolithic laser arrays having non-uniform lasers are disclosed. Example monolithic laser arrays provide a substantially uniform temperature distribution and include a substrate, a first set of lasers arranged on the substrate and separated by a first distance, and a second set of lasers arranged on the substrate and separated by a second distance greater than the first distance. The disclosed monolithic laser arrays yield an output with a substantially narrow optical spectral width.

### BACKGROUND

For laser arrays employing multiple lasers, operating temperature differences can have a negative impact on performance. In particular, in some lasers, high temperatures can affect lasing wavelength, leading to a wide optical spectral width.

The subject matter of the present disclosure is directed to overcoming, or at least reducing the effects of, one or more of the problems set forth above.

### SUMMARY OF THE DISCLOSURE

According to the present disclosure, monolithic laser arrays employ multiple individual lasers arranged with non-uniform spacing, the geometric design to yield an output with a narrow optical spectral width and a substantially uniform junction temperature distribution across the array.

These and other features of the present disclosure will become more fully apparent from the following description and appended claims, as set forth hereinafter.

### BRIEF DESCRIPTION OF THE DRAWINGS

To further clarify the above and other features of the present disclosure, a more particular description of the subject matter will be rendered by reference to specific examples thereof, which are illustrated in the appended drawings. It is appreciated that these drawings depict only some examples of the subject matter and are therefore not to be considered limiting of its scope.

FIG. 1A illustrates a monolithic array of lasers.

FIGS. 1B and 1C provide graphical illustrations of temperature variations of the monolithic array of lasers of FIG. 1A.

FIG. 2A illustrates another monolithic array of lasers.

FIGS. 2B and 2C provide graphical illustrations of temperature variations of the monolithic array of lasers of FIG. 2A.

FIG. 3A illustrates yet another monolithic array of lasers.

FIGS. 3B, 3C and 3D provide graphical illustrations of temperature variations of the monolithic array of lasers of FIG. 3A.

FIG. 4A illustrates yet another monolithic array of lasers.

FIGS. 4B, 4C and 4D provide graphical illustrations of temperature variations of the monolithic array of lasers of FIG. 4A.

FIGS. 5A to 5F provide graphical illustrations of example temperature distributions of a monolithic array of non-uniform 1D lasers.

FIGS. 6A and 6B provide graphical illustrations of temperature variations of the monolithic array of 1D lasers separated by a linear constant C, in accordance with the example of FIG. 2A.

FIGS. 7A and 7B provide graphical illustrations of temperature variations of a monolithic array of 2D lasers separated by a linear constant C, in accordance with the example of FIG. 4A.

### DETAILED DESCRIPTION OF THE DISCLOSURE

Monolithic laser arrays employing non-uniform spacing are disclosed. In particular, example monolithic laser arrays are arranged with a geometric design to yield an output with a narrow optical spectral width and a substantially uniform junction temperature distribution across the array.

As disclosed herein, spacing of the lasers in the monolithic laser array stabilizes temperature between lasers, providing an output with a narrow optical spectrum and a substantially uniform thermal performance across the lasers that comprise the array.

For many monolithic arrays employing multiple lasers (e.g., semiconductor lasers), the junction temperature in each semiconductor laser can be different. For example, a laser in the middle of a uniformly spaced laser array system will exhibit a relatively high operating temperature, in contrast to lasers at edges of the array with relatively low operating temperatures. As a result, a temperature difference across the array, from the laser with the highest operating temperature to the laser with the lowest operating temperature, can be substantial.

Such temperature differences can have a negative impact on laser performance. For instance, lasing output such as wavelength can be affected by the junction temperature. Thus, substantial temperature differences could lead to different lasing wavelengths for different lasers in the array. As a result, lasing optical spectral width from the array would be much wider than a single emitter.

To address these issues, disclosed is a geometric design with multiple lasers in a non-uniform arrangement on an array, thereby achieving a more uniform temperature distribution. By employing non-uniformly spaced lasers on the array, the temperature difference between the highest temperature laser and the lowest temperature laser can be reduced, advantageously leading to lasing spectral width reduction.

Example one-dimensional (1D) and two-dimensional (2D) monolithic laser arrays are disclosed, employing multiple semiconductor lasers arranged in a non-uniform pattern. Both 1D and 2D arrays are defined by laser-to-laser distances that are relatively sparse at a center of the array, and relatively more dense at edges of the array. Utilization of the disclosed geometric design, the junction temperature become uniform from laser to laser. The temperature difference between highest temperature to lowest temperature laser become smaller.

Heat simulation data validates performance of non-uniformly distributed laser arrays, both 1D and 2D laser arrays, exhibits more uniformly distributed heat and more stable laser junction temperatures across the multiple lasers, relative to a uniform laser distribution. In some examples, the temperature difference between a highest temperature laser in the array and a lowest temperature laser in the array is reduced substantially. In examples, the temperature difference in a non-uniform 1D array is reduced by approximately half (e.g., from approximately 20 K to approximately 10 K in 1D laser arrays) or more (e.g., from approximately 26 K to 11.5 K in 2D laser arrays) in pulse mode. For example, assuming a spectrum shift 0.5 nanometers per unit Kelvin, the spectral width may be reduced more than 5 nanometers using this novel geometric design.

In some examples, the multiple lasers employed can include one or more of a ridge type single quantum well (SQW) or multiple quantum well (MQW) semiconductor laser, a buried heterostructure (BH) SQW or MQW laser, a distributed-feedback (DFB) or Distributed Bragg reflector (DBR) laser, a Vertical-cavity surface-emitting laser (VCSEL), Photonic crystal surface-emitting lasers, InP based laser, GaAs based laser, GaSb based laser, GaN based laser, or other suitable laser. Although several disclosed examples are directed to a 1D laser array and a 2D laser array, in some examples a three-dimensional (3D) laser array can employ the principles disclosed herein. Further, although one or more laser types and/or wavelengths are discussed in the several examples, application of the concepts disclosed herein are not limited to a particular laser or wavelength. In some examples, lasers are disclosed that operate with wavelengths of 940 nanometers, 980 nanometers, 1350 nanometers, 1480 nanometers, and/or 1550 nanometers, as a list of non-limiting examples.

The disclosed monolithic laser array can provide benefits to a variety of applications, such as three-dimensional sensing, including light detection and ranging (LIDAR), telecommunications transmissions, as a list of non-limiting examples.

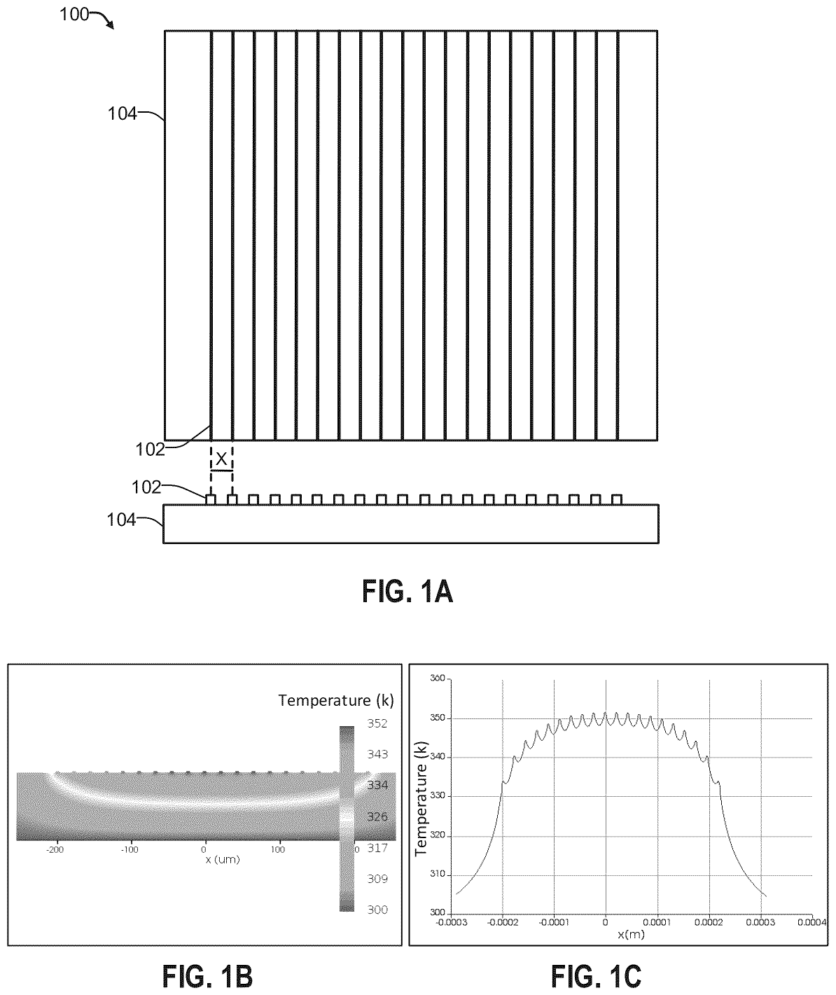

FIG. 1A illustrates a monolithic array of lasers 100. As shown, the array 100 is arranged as a one-dimensional (1D) array, with uniformly spaced lasers 102 on a substrate 104. In the example of FIG. 1A, a distance X between lasers 102 within the array 100 can be fixed (e.g., approximately 22 micrometers). In other words, the distance or spacing between each laser 102 and each adjacent laser 102 is uniform. In some examples, the 1D laser can be a ridge laser, or other similarly configured laser device.

FIGS. 1B and 1C provide graphical illustrations of temperature variations of the monolithic array of lasers of FIG. 1A. The illustrates provide data from a laser array 100 employing a heat sink of approximately 300 degrees K with an operational current of approximately 6 A and a pulse mode with a duty cycle of approximately 5%. The graphs show the maximum ridge temperature T(K) of approximately 352 degrees K, a minimum ridge temperature T(K) of approximately 332 degrees K, with a difference of approximately 20 degrees K. As shown in the example of FIG. 1C, peak temperatures represent corresponding laser junction temperatures.

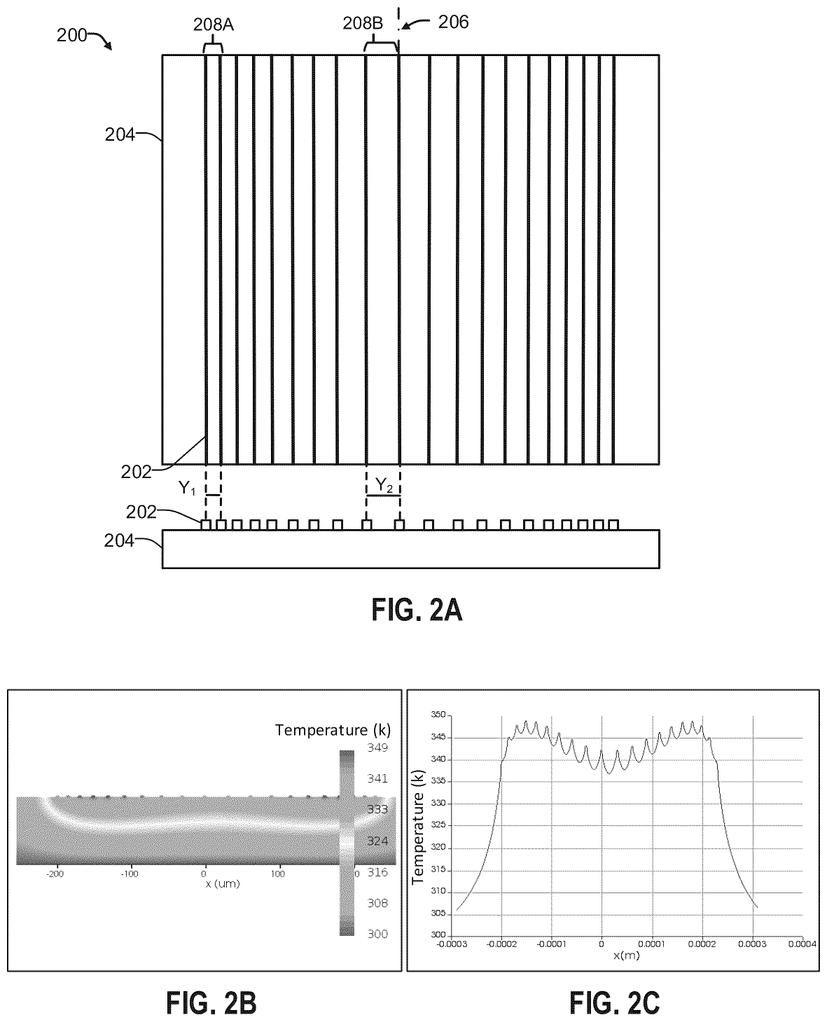

In an effort to lessen the difference between maximum and minimum ridge temperatures, non-uniform laser arrays are disclosed. The example of FIG. 2A illustrates another monolithic array of lasers 200. As shown, the array 200 is arranged as a one-dimensional (1D) array, with non-uniformly spaced lasers 202 on a substrate 204.

In the disclosed example, the lasers 202 arranged in a middle section of the array (e.g., closer to centerline 206) have a greater space between them, in contrast to the lasers arranged in an edge section, where the lasers have a smaller space therebetween.

The change in distance Y₁ between lasers 202 of a first set 208A and the change in distance Y₂ between lasers 202 of a second set 208B can be calculated to form a consistent difference across the array. In an example, distances between adjacent lasers can be calculated by a linear change (e.g., in accordance with Equations 1 to 4 disclosed herein). In another example, distances between adjacent lasers can be calculated by an exponential change. In yet another example, distances between adjacent lasers can be calculated by a polynomial expression. In some examples, a distance between a first set of lasers within the array can be calculated by one of a linear, and exponential, or a polynomial change, whereas a distance between a second set of lasers within the array can be calculated by another of the linear, exponential, or polynomial change.

For example, the distance between lasers within the array can vary based on a distance from a centerline 206 of the array. In the example of FIG. 2A, the lasers 202 arranged near the centerline 206 are separated by a greater distance than lasers 202 arranged at edges of the substrate 204.

A distance between lasers 202 within the array 200 can be calculated or determined based on one or more equations. For instance, a distance value Y can be calculated via example Equation 1 or example Equation 2, depending on whether the distance between lasers is to be reduced or expanded, respectively:

Y=X−NC Equation 1:

Y=X+NC Equation 2:

where X is a representative distance between lasers, N is a numerical integer (e.g., 1, 2, 3, 4, 5, etc.), and C is a constant that is determined based on a desired size of the monolithic laser array, a particular application for the monolithic laser array, or other suitable measure.

In the example of FIG. 2A, a first distance Y₁ between a first set of lasers 208A can be calculated by example Equation 3, whereas a second distance Y₂ between a second set of lasers 208B can be calculated by example Equation 4:

Y₁=X−4C Equation 3:

Y₂=X+₅C Equation 4:

In the examples of Equations 1 to 4, X can be representative of a uniform distance between lasers (e.g., approximately 22 micrometers), and C is a constant based on a desired size of the monolithic laser array (e.g., approximately 2 micrometers).

Although Equations 1 to 4 represent X as the distance between uniformly distributed lasers (e.g., distance X as shown in FIG. 1A), X may be any value and many not necessarily have an association with a uniformly distributed laser array.

In some examples, a given laser may be included in both the first and second sets of lasers, such that which set the laser and an adjacent laser comprise the first or second set is defined by the distance between an adjacent laser.

Although illustrated as two sets of lasers, three, four, five, six, seven, eight, nine, ten or more sets of lasers could be distributed about the monolithic laser array. Each set may have a different distance between lasers within the set and/or between adjacent sets of lasers, or two or more sets may have the same distance therebetween lasers and/or adjacent sets.

FIGS. 2B and 2C provide graphical illustrations of temperature variations of the monolithic array of lasers of FIG. 2A. For example, a heat sink of approximately 300 degrees K with an operational current of approximately 6 A with a pulse mode of approximately 5% duty cycle. In the example of FIGS. 2B and 2C, heat simulations validate the concept that non-uniform laser array distribution leads to a more uniform heat distribution.

For instance, the example of FIG. 1C shows the maximum ridge temperature T(K) of 352, a minimum ridge temperature T(K) of 332, with a difference of approximately 20 degrees K. In the example of FIG. 2C, a maximum ridge temperature T(K) of 349, a minimum ridge temperature T(K) of 339, yielding a difference of approximately 10 degrees K. Thus, the non-uniform distribution of lasers on the array shows a smaller difference between maximum and minimum ridge temperatures in comparison to the uniform laser distribution array.

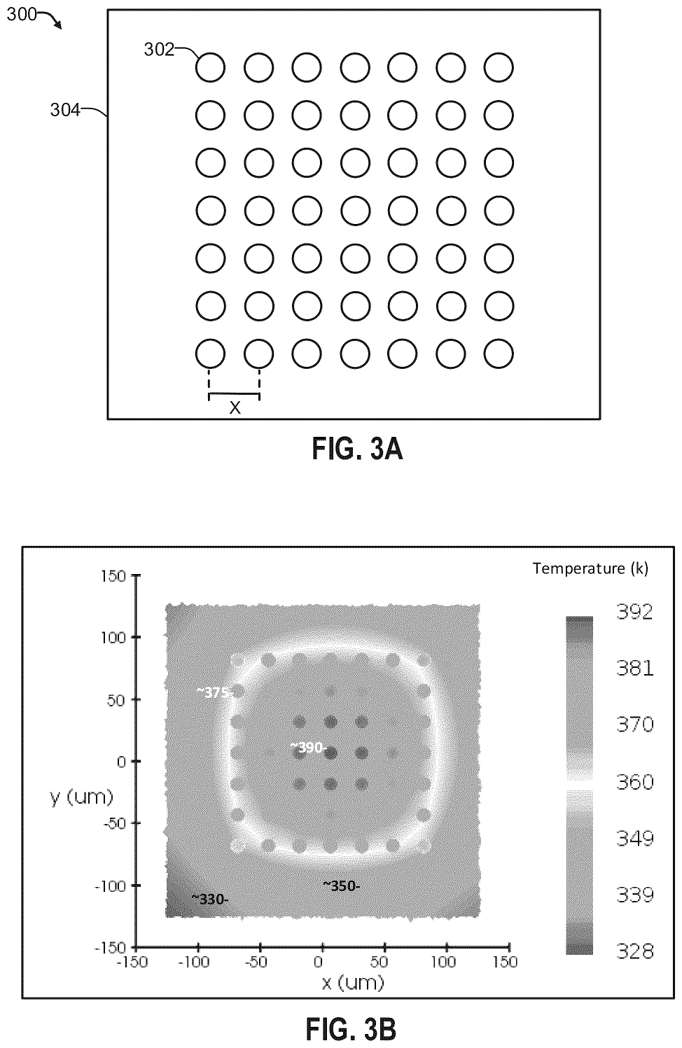

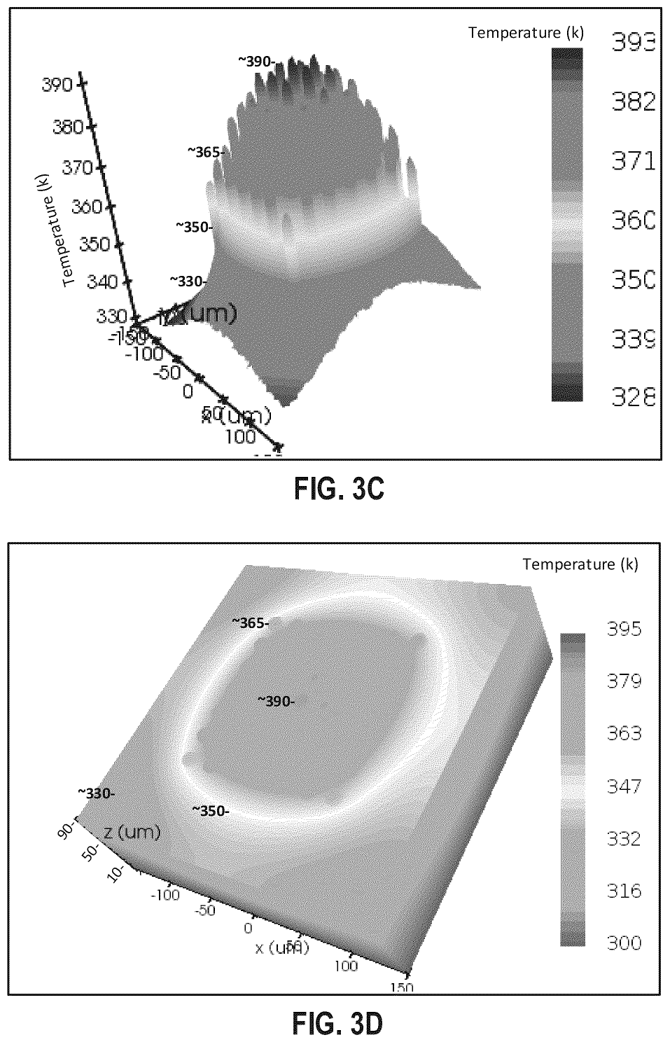

FIG. 3A illustrates yet another monolithic array of lasers 300. As shown, the array 300 is arranged as a two-dimensional (2D) array, with uniformly spaced lasers 302 on a substrate 304. In the example of FIG. 3, a distance X between lasers 302 within the array 300 can be fixed (e.g., approximately 22 micrometers). In other words, the distance or spacing between each laser 302 and each adjacent laser 302 is uniform.

FIGS. 3B, 3C and 3D provide graphical illustrations of temperature variations of the monolithic array of lasers of FIG. 3A.

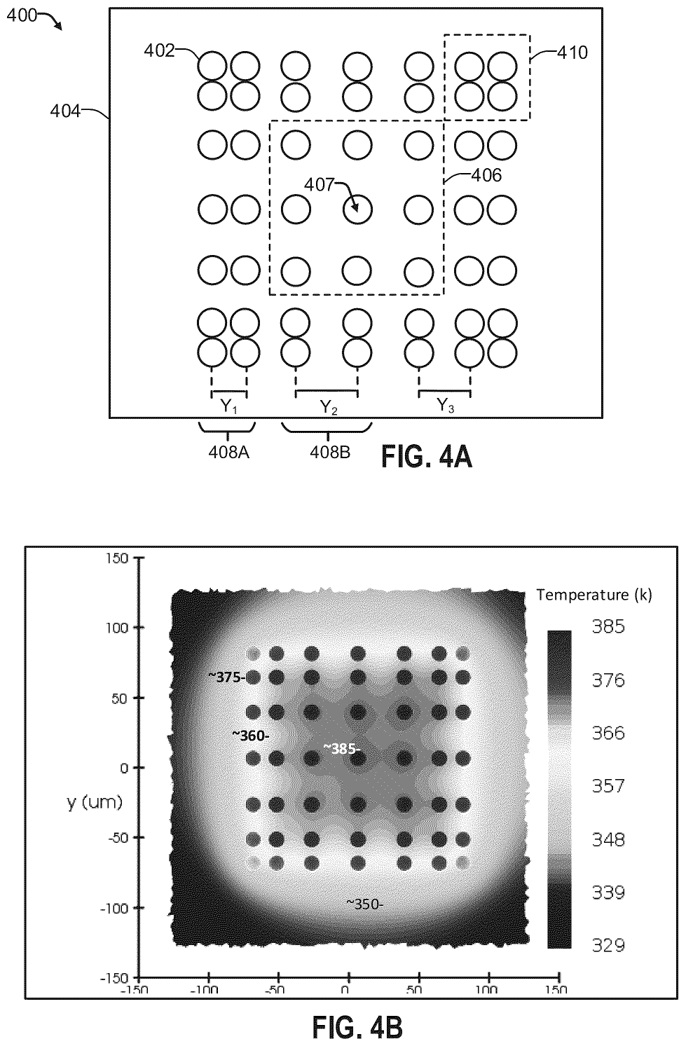

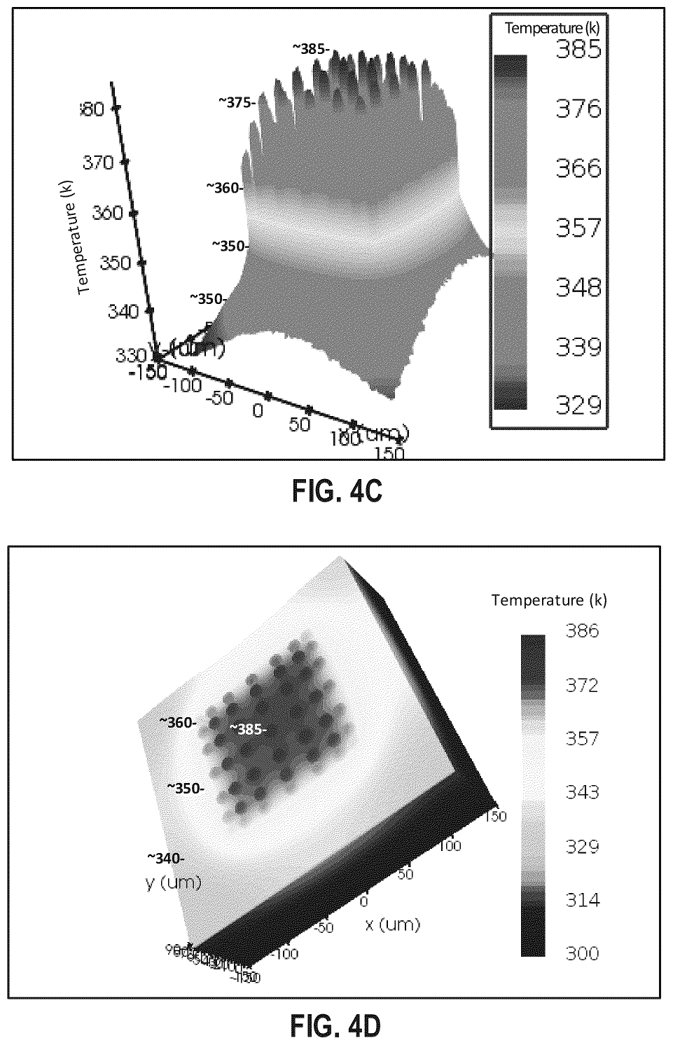

Similar to the array 100 of FIG. 1A, in an effort to lessen the difference between maximum and minim ridge temperatures, non-uniform laser 2D arrays are disclosed. FIG. 4A illustrates yet another monolithic array of lasers 400. As shown, the array 400 is arranged as a two-dimensional (2D) array, with non-uniformly spaced lasers 402 on a substrate 404.

In the disclosed example, the lasers 402 arranged in a middle section 406 of the array (e.g., at, about, or near a geometric center 407 of the array 400) have a greater space between them, in contrast to the lasers arranged in an edge section 410, where the lasers have a smaller space therebetween.

The change in distance Y₁ between lasers 402 of a first set 408A within edge section 410 and the change in distance Y₂ between lasers 402 of a second set 408B within middle section 406 can be calculated to form a consistent difference across the array. In an example, distances between adjacent lasers can be calculated by a linear change (e.g., in accordance with Equations 1 to 4 disclosed herein). In the example of Equations 3 and 4, X can be assigned a value of approximately 25 micrometers, N can be assigned a value of 1, and C can be assigned a value of approximately 8 micrometers. In some examples, the value of X can equate to Y₃, or the distance separating first set 408A and second set 408B.

In another example, distances between adjacent lasers can be calculated by an exponential change. In yet another example, distances between adjacent lasers can be calculated by a polynomial expression. In some examples, a distance between a first set of lasers within the array can be calculated by one of a linear, and exponential, or a polynomial change, whereas a distance between a second set of lasers within the array can be calculated by another of the linear, exponential, or polynomial change.

FIGS. 4B, 4C and 4D provide graphical illustrations of temperature variations of the monolithic array of lasers of FIG. 4A.

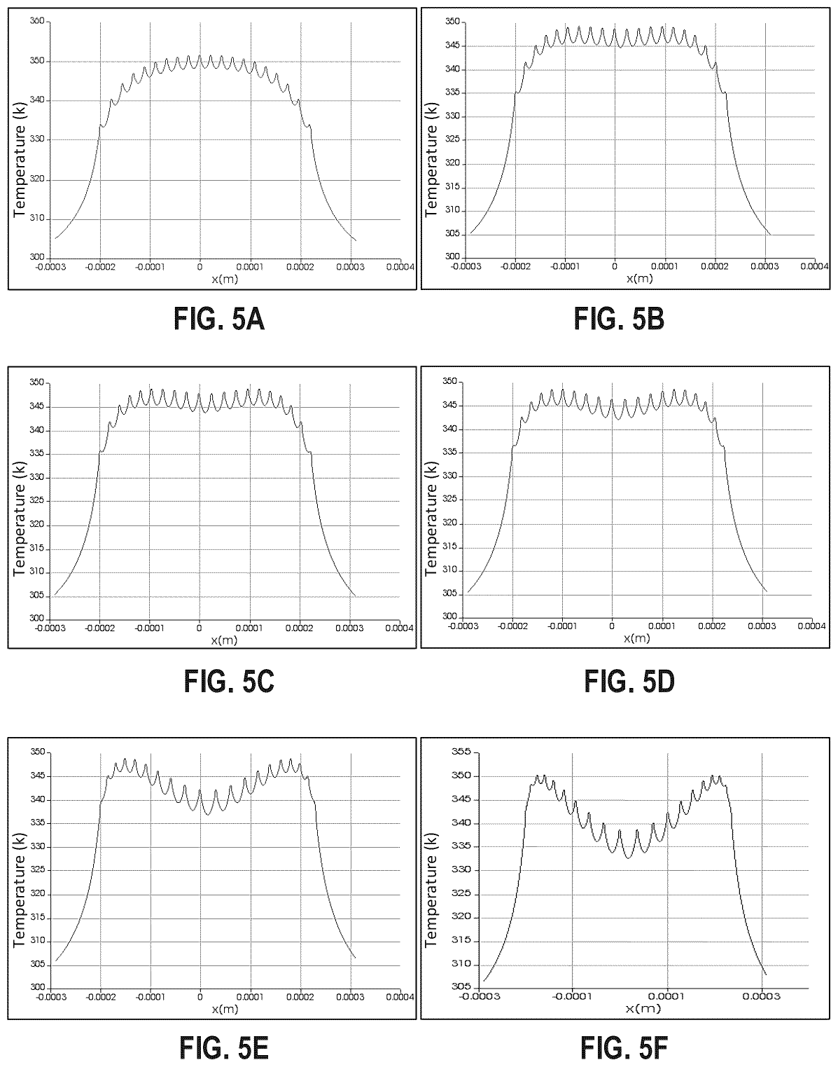

FIGS. 5A to 7B provide additional graphical illustrations of temperature data of the non-uniform laser arrays disclosed herein, including comparisons to uniform laser arrays.

FIGS. 5A to 5F provide graphical illustrations of example temperature distributions of a monolithic array of non-uniform 1D lasers where the constant C varies, as applied to Equations 3 and 4. For example, FIG. 5A illustrates an example temperature distribution with a C value of 0 micrometers, FIG. 5B illustrates an example temperature distribution with a C value of 0.55 micrometers, FIG. 5C illustrates an example temperature distribution with a C value of 0.7 micrometers, FIG. 5D illustrates an example temperature distribution with a C value of 1 micrometers, FIG. 5E illustrates an example temperature distribution with a C value of 2 micrometers, and FIG. 5F illustrates an example temperature distribution with a C value of 3 micrometers.

As shown, maximum and minimum temperatures can vary depending on the selected value of C, as well as the difference between the maximum and minimum temperature values.

Moreover, simulated data show a 2D uniform laser array 300 (having a uniform laser distance of approximately 25 micrometers) yields a maximum ridge temperature T(K) of approximately 392 degrees K, and a minimum ridge temperature T(K) of approximately 366 degrees K, having a difference of approximately 26 degrees K. By contrast, experimental data show a 2D non-uniform laser array 400 (having a non-uniform laser distance with linear changes of approximately 25 micrometers +/−NC, in accordance with Equations 1-4) yields a maximum ridge temperature T(K) of approximately 385 degrees K, a minimum ridge temperature T(K) of approximately 372 degrees K, with a difference of approximately 13 degrees K. Accordingly, the heat simulation data validate the concept that non-uniform distributed 2D arrays leads to more uniform heat distribution, which will narrow the optical spectral width.

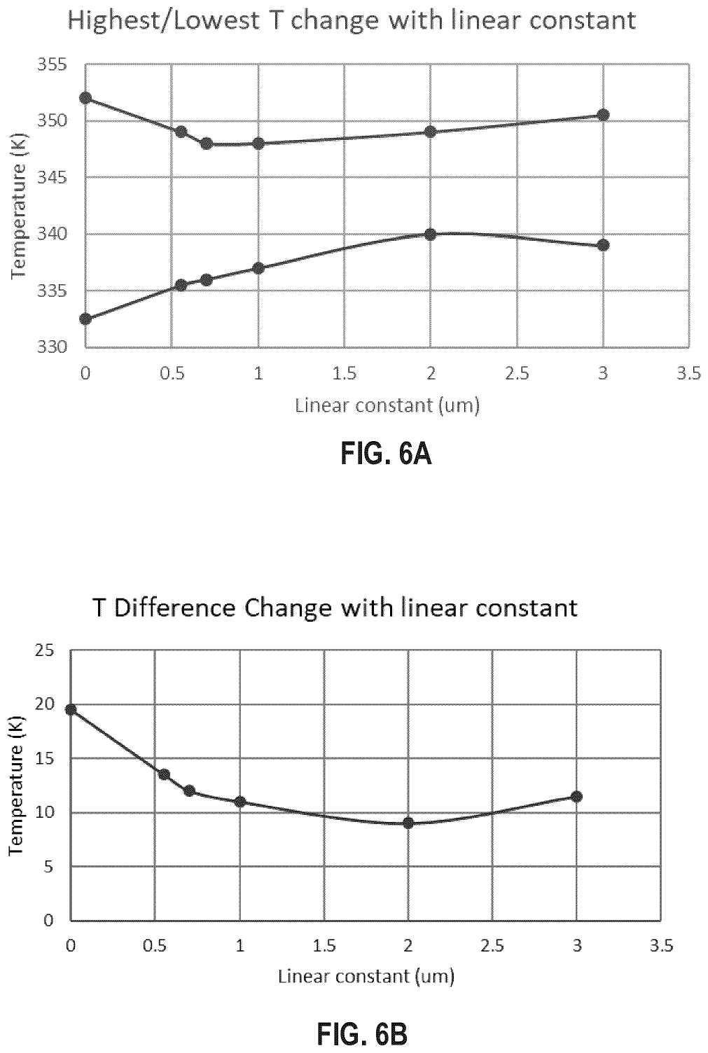

FIGS. 6A and 6B provide graphical illustrations of temperature variations of the monolithic array of 1D lasers separated by a linear constant C, in accordance with the example of FIG. 2A. For example, over a range of values for constant C (applied to Equations 1-4), the temperature difference between a high temperature laser and a low temperature laser is reduced from approximately 20 degrees K to approximately 9.5 degrees K.

For example, for constant value C=0, a maximum ridge temperature T(K) is approximately 352 degrees K, and a minimum ridge temperature T(K) is approximately 332 degrees K, with a difference of approximately 20 degrees K.

By contrast, for constant value C=2, a maximum ridge temperature T(K) of approximately 349.5 degrees K, and a minimum ridge temperature T(K) of approximately 340 degrees K, with a difference of approximately 9.5 degrees K.

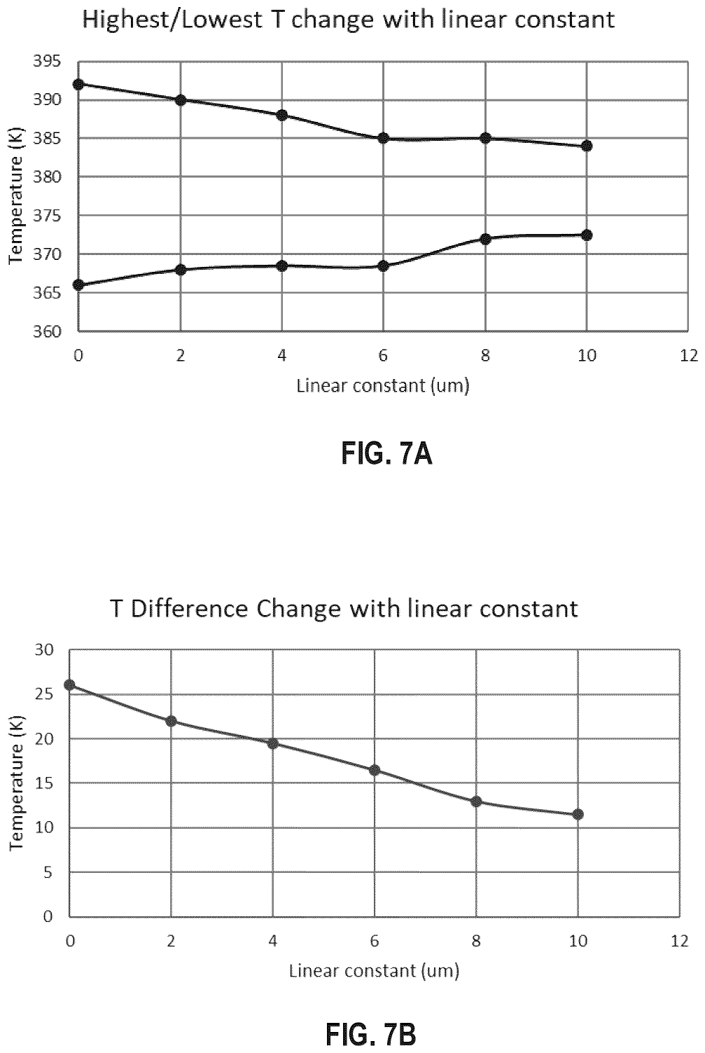

FIGS. 7A and 7B provide graphical illustrations of temperature variations of a monolithic array of 2D lasers separated by a linear constant K, in accordance with the example of FIG. 4A. For example, over a range of values for constant C (applied to Equations 1-4), the temperature difference between a high temperature laser and a low temperature laser is reduced from approximately 25 degrees K to approximately 11.5 degrees K.

For example, for a 2D non-uniform laser array 400, when a distance between adjacent lasers is calculated with a linear constant C=0, a maximum ridge temperature T(K) equals approximately 392 degrees K, and a minimum ridge temperature T(K) equals approximately 367 degrees K. As a result, a difference between maximum and minimum ridge values is approximately 25 degrees K. At a linear constant value of C=10, the difference drops to 11.5 degrees K. Accordingly, the heat simulation data validate the concept that non-uniform distributed 2D arrays leads to more uniform heat distribution, which will narrow the spectral width.

The foregoing description of preferred and other embodiments is not intended to limit or restrict the scope or applicability of the inventive concepts conceived of by the Applicants. It will be appreciated with the benefit of the present disclosure that features described above in accordance with any embodiment or aspect of the disclosed subject matter can be utilized, either alone or in combination, with any other described feature, in any other embodiment or aspect of the disclosed subject matter.

1. A monolithic laser array, comprising:
a first set of lasers separated by a first distance; and
a second set of lasers separated by a second distance greater than the first distance.

2. The monolithic laser array of claim 1, wherein one or more lasers of the first or second set of lasers are one-dimensional (1D) lasers.

3. The monolithic laser array of claim 2, wherein the second set of 1D lasers is arranged proximate a centerline of the array.

4. The monolithic laser array of claim 3, wherein the first set of 1D lasers is arranged opposite the centerline relative to a position of the second set of 1D lasers on the array.

5. The monolithic laser array of claim 2, wherein the first or second set of 1D lasers includes two lasers.

6. The monolithic laser array of claim 1, wherein one or more lasers of the first or second set of lasers are two-dimensional (2D) lasers.

7. The monolithic laser array of claim 6, wherein the second set of 2D lasers is arranged about a center of the array.

8. The monolithic laser array of claim 7, wherein the first set of 2D lasers is arranged opposite the center relative to a position of the second set of 2D lasers on the array.

9. The monolithic laser array of claim 6, wherein the first or second set of 2D lasers includes four lasers.

10. The monolithic laser array of claim 1, wherein the first distance is calculated by one of a linear equation, an exponential equation, or a polynomial expression.

11. The monolithic laser array of claim 1, wherein the first distance Y₁ is calculated by equation Y₁=X−NC, where X is a representative distance between lasers, N is a numerical integer, and C is a constant.

12. The monolithic laser array of claim 1, wherein the second distance Y₂ is calculated by equation Y₂=X+NC, where X is a representative distance between lasers, N is a numerical integer, and C is a constant.

13. The monolithic laser array of claim 1, wherein the first distance or the second distance is in a range between 5-30 micrometers.

14. The monolithic laser array of claim 1, wherein one or more lasers of the first or second set of lasers is one or more of a ridge type single quantum well (SQW) or multiple quantum well (MQW) semiconductor laser, a buried heterostructure (BH) SQW or MQW laser, a distributed-feedback (DFB) or Distributed Bragg reflector (DBR) laser, a Vertical-cavity surface-emitting laser (VCSEL), photonic crystal surface-emitting lasers, InP based laser, GaAs based laser, GaSb based laser, GaN based laser, or other suitable laser.

15. The monolithic laser array of claim 1, further comprising a substrate to support the first and second sets of lasers.

16. A monolithic laser array to provide a substantially uniform temperature distribution, comprising:
a substrate;
a first set of lasers arranged on the substrate and separated by a first distance; and
a second set of lasers arranged on the substrate and separated by a second distance greater than the first distance.

17. The monolithic laser array of claim 16, further comprising a third set of lasers arranged on the substrate and separated by a third distance.

18. The monolithic laser array of claim 16, wherein one or more lasers of the first or second set of lasers are one-dimensional (1D) lasers,
a first pair of the first and second sets of 1D lasers arranged on a first portion of the substrate, and a second pair of the first and second sets of 1D lasers arranged on a second portion of the substrate, the first and second portions being separated by a centerline of the array.

19. The monolithic laser array of claim 16, wherein one or more lasers of the first or second set of lasers are two-dimensional (2D) lasers.

20. The monolithic laser array of claim 19, wherein the second set of 2D lasers is arranged about a center of the substrate, and one or more of the first sets of 2D lasers are arranged on the substrate about the second set.
